(19) United States
(12) Patent Application Publication
(10) Pub. No.: US 2021/0245558 A1
(43) Pub. Date: Aug. 12, 2021

(54) WHEEL WELL CAPACITIVE PROXIMITY SENSOR SYSTEMS AND METHODS

(71) Applicant: Ford Global Technologies, LLC, Dearborn, MI (US)

(72) Inventors: Stuart C. Salter, White Lake, MI (US); John Robert Van Wiemeersch, Novi, MI (US); Paul Kenneth Dellock, Northville, MI (US); Anthony Dwayne Cooprider, Rochester Hills, MI (US); Annette Huebner, Highland, MI (US)

(73) Assignee: Ford Global Technologies, LLC, Dearborn, MI (US)

(21) Appl. No.: 16/784,184

(22) Filed: Feb. 6, 2020

(51) Int. Cl. B60C 23/04; H03K 17/955; G01D 5/24

(52) U.S. Cl. CPC B60C 23/0442; G01D 5/24; H03K 17/955

(57) ABSTRACT

This disclosure is directed to systems and methods that determine theft of a wheel on a vehicle using a capacitive proximity sensor system. The systems and methods determine that a vehicle is parked, and then receives information indicative of a capacitance at a first sensor positioned proximate a wheel well of the vehicle. The systems and methods further determine, based on the information, that the capacitance exceeds a first threshold. The systems and methods further determine, based on the information, that the capacitance exceeds the first threshold for a period of time that exceeds a second threshold. The systems and methods further send a message to a mobile device in response to capacitance exceeding the first threshold for the period of time that exceeds the second threshold.

### TECHNICAL FIELD

The present disclosure relates to capacitive proximity sensor systems and methods for use in a vehicle environment.

### BACKGROUND

The ability to determine the difference between when a wheel on a vehicle is being stolen, being serviced, or being replaced often times requires the aide of a human to observe individuals who are within the vicinity of the vehicle. Car alarm systems often require a user of a vehicle to deactivate the car alarm system prior to servicing the wheel or replacing the wheel. Wheel locks may prevent thieves from removing wheels from a vehicle, but this may also require the user to keep track of a key that is needed to unlock the locks on the wheels when the wheels need to be serviced or replaced. Other car alarm systems include cameras that detect motion within a field of view of the camera, however these systems perform poorly in dimly-lit environments. Further, these systems require a processor to execute detection and recognition algorithms, which can be costly given the computational complexity of these detection and recognition algorithms. Accordingly, current antitheft systems may require participation by the user, or they are costly and work only in well-lit environments.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1A depicts an illustrative capacitive proximity sensor system integrated into a wheel well molding in accordance with the present disclosure.

FIG. 1B depicts a cross-sectional view taken along lines 1B′-1B′ in FIG. 1A, depicting an illustrative capacitive sensor system integrated into a fender in accordance with the present disclosure.

FIG. 2 depicts illustrative capacitive sensing fields generated by capacitive proximity sensor systems at each tire of a vehicle in accordance with the present disclosure.

FIG. 3 is a graphical representation of a capacitive proximity sensor system detecting a person within the capacitive proximity sensor system's capacitive sensing field in accordance with the present disclosure.

FIG. 4 is a flowchart of an example method of the present disclosure related to detecting a person in a capacitive sensing field of a capacitive proximity sensor system.

FIG. 5 is a flowchart of an example method of the present disclosure related to detecting a person in a capacitive sensing field of a capacitive proximity sensor system.

FIG. 6 depicts an illustrative architecture in which techniques and structures for providing the systems and methods disclosed herein may be implemented.

### DETAILED DESCRIPTION

### Overview

The systems and methods disclosed herein are configured to detect an individual as they approach a vehicle having a capacitive proximity sensor system integrated into a wheel well molding of the vehicle in accordance with the disclosure herein. Such a capacitive proximity sensor system may include two capacitive sensors that are integrated into the wheel well molding of the vehicle using a two shot process. A two shot process, or double shot molding process may include a manufacturing process that produces the wheel well by disposing a plastic in a mold of the wheel well. This may be referred to as the first shot or first step in the two shot process. The second step or second shot includes a primer being injected into, or applied to, the plastic wheel well in order to make a capacitive sensor.

The capacitive sensors may be integrated into the wheel well molding by way of application of a conductive primer to the plastic of the wheel well molding. The conductive primer creates an electrostatic field similar to an electrostatic field generated between two plates of a capacitive element. When an object, for example an automobile, person, or animal such as a dog disturbs the electrostatic field generated by the capacitive sensors, processors integrated in the vehicle, such as inside of the wheel well molding, may measure a voltage associated with the disturbance of the electrostatic field and determine the location of the object relative to the wheel well, for which its location can be tracked over a period of time. Utilizing multiple capacitive sensors, for instance, one at each wheel well, may enable the processor to track the location of the object over time by measuring a voltage associated with the electrostatic field disturbances of each of the capacitive sensors over time, as the object moves toward, or along the length of the car or from side to side around the vehicle.

In some embodiments, the present disclosure leverages a low energy wireless radio to communicate messages from a processor of the vehicle to a mobile device associated with the user of the vehicle who is within the vicinity of the vehicle to prevent an alarm from sounding when the user is servicing a wheel of the vehicle. In addition, the processor may broadcast a message to devices within the vicinity of the vehicle, that are not associated with the user, indicating that the one or more cameras are recording footage from a field of view in front of the wheel well. This message may be sent if the device of the user is not within the vicinity of the vehicle.

### Illustrative Embodiments

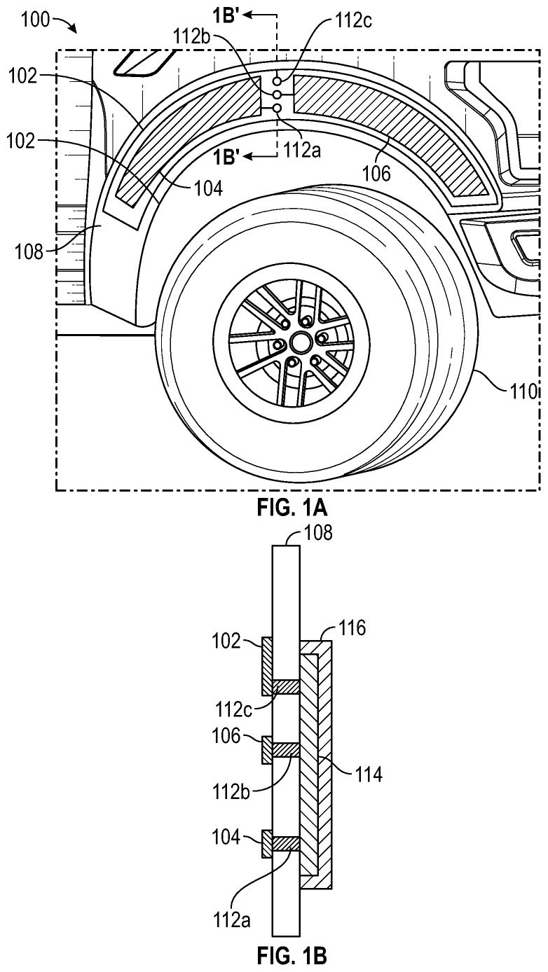

FIG. 1 depicts a fender portion 100 of a vehicle in which techniques and structures of the present disclosure may be implemented. Fender portion 100 may also be referred to as a wheel well. The fender portion 100 may include a wheel 110, fender molding 108, driven ground 102, capacitive sensor 104, capacitive sensor 106, connector 112a, connector 112b, and connector 112c. Fender molding 108 may be plastic, and may be treated with a conductive primer, such as Cabot VULCAN XCmax™ 22 applied in a 1 mil thickness, to create a capacitive element, such as capacitive sensors 104 and/or capacitive sensor 106. Conductive primers can be used to increase the efficiency of spray painting (for example, using less paint). That is, after a plastic is molded into fender molding 108, one or more portions of the plastic may be treated with the conductive primer. In FIG. 1, two portions of fender molding 108 are treated with the conductive primer. The first portion corresponds to capacitive sensor 104 and the second portion corresponds to capacitive sensor 106. Because capacitive sensor 104 and capacitive sensor 106 are capacitive elements, both capacitive sensors may each generate separate electrostatic fields within the vicinity of fender molding 108. The electrostatic field produced by the capacitive sensors may be three-dimensional. That is, the electrostatic fields generated by the capacitive sensors may extend away from the vehicle in a three-dimensional area. Capacitive sensor 104 and capacitive sensor 106 may be on the outside of fender molding 108 and may be painted over with paint that is the same color as the vehicle, or a different color than the vehicle.

The outside of the fender portion corresponding to capacitive sensor 104 may be treated with the conductive primer. The outside of the fender portion corresponding to capacitive sensor 104 may function equivalently to a first plate in a capacitive element. The inside of the fender portion corresponding to capacitive sensor 104 may function equivalently to a second plate in the capacitive element. The space between the outside of the fender portion of capacitive sensor 104 and the inside of the fender portion of capacitive sensor 104 may be hollow thereby creating a dielectric consistent with air between the first plate and the second plate. The electrostatic field may be formed between the first plate and the second plate. In some embodiments, the sheet metal of the vehicle may function equivalently to the second plate of a capacitive element.

The outside of the fender portion corresponding to capacitive sensor 106 may be treated with the conductive primer and the inside of the fender portion corresponding to capacitive sensor 106 may be treated with the conductive primer. The outside of the fender portion corresponding to second capacitive sensor 106 may function equivalently to a first plate in a capacitive element. The inside of the fender portion corresponding to capacitive sensor 106 may function equivalently to a second plate in the capacitive element. The space between the outside of the fender portion of capacitive sensor 106 and the inside of the fender portion of capacitive sensor 106 may be hollow thereby creating a dielectric consistent with air between the first plate and the second plate. The electrostatic field may be formed between the first plate and the second plate. In some embodiments, the sheet metal of the vehicle may function equivalently to the second plate of a capacitive element. Thus, both capacitive sensor 104 and capacitive sensor 106 may have a similar arrangement.

Alternatively, the capacitive sensors 104 and 106 may be comprised of the conductive primer on merely the outside of the fender 108 (also referred to herein as the fender molding 108), or may be comprised of the primer on merely the inside of the fender 108. In addition, a driving ground 102 may also be made of conductive primer or conductive rubber, and be positioned co-planar to the capacitive sensors 104 and 106 on the outside of the fender 108. The driven ground 102 may reduce sensitivity to environmental issues such as moisture (for example, rain, snow mud, etc.).

With reference to FIG. 1B, a cross-sectional view of the fender 108 taken along line 1B′-1B′ is shown. Capacitive sensor 104 and capacitive sensor 106 may be connected to a processor (not shown) housed on a printed circuit board (PCB) 114 attached to the vehicle, such as on the inside of the fender 108. A silicon over molding 116 may be formed over the PCB 114 for protection. The capacitive sensors 104, 106 and driven ground 102 may be connected to the PCB 114 by connections 112a, 112b, 112c, respectively, which may be conductive studs or bolts. The connectors may comprise an elastomeric inter-connector, such as those available from Shin-Etsu Polymer Europe B.V. In some embodiments, the connectors 112a, 112b, and 112c may be an insert molded stud, or in other embodiments, the connectors 112a, 112b, and 112c may be conductive rubber providing electrical connection between the capacitive sensors 104, 106 and the driven ground 102 to the PCB 114 on the opposite side of the fender 108, as illustrated in an example embodiment in FIG. 1B. The Capacitive sensor 104, capacitive sensor 106 and driven ground 102 may be integrated into fender molding 108 via a two shot molding process. The two shot molding process may also be referred to as a double molding process.

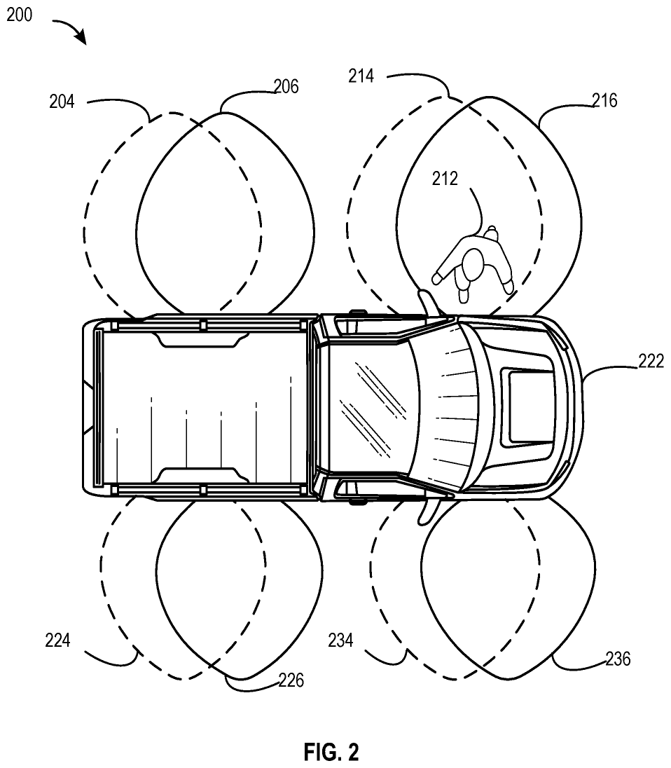

FIG. 2 depicts illustrative capacitive sensing fields generated by capacitive proximity sensor systems at each wheel well of a vehicle, in accordance with the present disclosure. The sensors could be integrated at other locations around the car, such as into bumpers, door handles, and/or trim pieces. Further, the sensors could be mounted on the tail or rear of the vehicle and/or the underbody in locations where a spare tire may be mounted. Illustrative environment 200 depicts electrostatic fields generated by each of a plurality of capacitive proximity sensor systems located at each wheel well. Each capacitive proximity sensor system may include a first capacitive sensor (e.g., the first capacitive sensor 104 or capacitive sensor 106), and one or more additional capacitive sensors (e.g., the second capacitive sensor 104 or capacitive sensor 106). The capacitive proximity sensor system may further include a first connector (e.g., a stud or bolt of a conductive material) connecting the first capacitive sensor to a processor on a PCB (e.g., PCB 114), and a second connector (e.g., a stud or bolt of a conductive material) connecting the second capacitive sensor to the processor on the PCB (e.g., PCB 114). The capacitive proximity sensor system may also include a third connector (e.g., a stud or bolt of a conductive material) that connects a driven ground to the processor on the PCB (e.g., PCB 114).

In illustrative environment 200 there are four capacitive proximity sensor systems (i.e., a first capacitive proximity sensor system corresponding to electrostatic fields 204 and 206, a second capacitive proximity sensor system corresponding to electrostatic fields 214 and 216, a third capacitive proximity sensor system corresponding to electrostatic fields 224 and 226, and a fourth capacitive proximity sensor system corresponding to electrostatic fields 234 and 236). Each of the first, second, third, and fourth capacitive proximity sensor systems are comprised of two capacitive sensors. Each of the capacitive sensors in each of the four capacitive proximity sensor systems on vehicle 222 generate an electrostatic field. A first capacitive sensor, of the first capacitive proximity sensor system, may generate electrostatic field 204, and a second capacitive sensor, of the first capacitive proximity sensor system, may generate electrostatic field 206. A first capacitive sensor, of the second capacitive proximity sensor system, may generate electrostatic field 214, and a second capacitive sensor, of the second capacitive proximity sensor system, may generate electrostatic field 216. A first capacitive sensor, of the third capacitive proximity sensor system, may generate electrostatic field 224, and a second capacitive sensor, of the third capacitive proximity sensor system, may generate electrostatic field 226. A first capacitive sensor, of the fourth capacitive proximity sensor system, may generate electrostatic field 234, and a second capacitive sensor, of the fourth capacitive proximity sensor system, may generate electrostatic field 236.

As an individual (e.g., individual 212) approaches vehicle 222, and more specifically, as the individual approaches an area next to vehicle 222 that is encompassed by electrostatic field 214 and electrostatic field 216, the second capacitive proximity sensor system may determine that an object is approaching or next to the fender portion housing the second capacitive proximity sensor system.

As explained above, the first capacitive sensor may be created using a conductive primer that is integrated into the fender portion of vehicle 222. The conductive primer may be integrated into the fender portion in such a way to generate an electrostatic field between two portions of a given capacitive sensor. For example, the outside of the fender portion corresponding to the first capacitive sensor may be treated with the conductive primer and the inside of the fender portion corresponding to the first capacitive sensor may also be treated with the conductive primer. The outside of the fender portion corresponding to the first capacitive sensor may function equivalently to a first plate in a capacitive element. The inside of the fender portion corresponding to the first capacitive sensor may function equivalently to a second plate in the capacitive element. The space between the outside of the fender portion of the first capacitive sensor and the inside of the fender portion of the first capacitive sensor may be hollow thereby creating a dielectric consistent with air between the first plate and the second plate. The electrostatic field may be formed between the first plate and the second plate. In some embodiments, the sheet metal of the vehicle may function equivalently to the second plate of a capacitive element.

The outside of the fender portion corresponding to the second capacitive sensor may be treated with the conductive primer and the inside of the fender portion corresponding to the second capacitive sensor may be treated with the conductive primer. The outside of the fender portion corresponding to the second capacitive sensor may function equivalently to a first plate in a capacitive element. The inside of the fender portion corresponding to the second capacitive sensor may function equivalently to a second plate in the capacitive element. The space between the outside of the fender portion of the second capacitive sensor and the inside of the fender portion of the second capacitive sensor may be hollow thereby creating a dielectric consistent with air between the first plate and the second plate. The electrostatic field may be formed between the first plate and the second plate. In some embodiments, the sheet metal of the vehicle may function equivalently to the second plate of a capacitive element. Thus, both the first capacitive sensor and second capacitive sensor for each capacitive proximity sensor system may have a similar arrangement.

The electrostatic field between the first plate and the second plate may be generated responsive to an alternating voltage applied across the first plate and the second plate. Positively charged particles will accumulate on either the first plate or the second plate, and negatively charged particles will accumulate on the other plate. The accumulation of the positively charged particles on one of the two plates and the accumulation of the negatively charged particles on the other plate will cause an electrostatic field to be generated between the plate with the positively charged particles and the plate with the negatively charged particles. The electrostatic field lines will point in a direction from the plate with the accumulated positively charged particles to the plate with the accumulated negatively charged particles. That is the electrostatic field will be generated by the positively charged particles and terminate on the negatively charged particles. When individual 212 enters the electrostatic fields 214 and 216, the individual's flesh will serve to change the dielectric constant between the plate with the positively charged particles and the plate with the negatively charged particles. Because the dielectric constant associated with air is known, a detector circuit on the PCB can determine a change in the capacitance due to the presence of individual 212. The detector circuit may send one or more signals to the processor of the capacitive proximity sensor system, which may in turn process the one or more signals to determine that individual 212 is a human. The processor may be equipped with one or more instruction sets that enable the processor to determine a difference between a human being and an animal such as a dog, deer, cat, etc. Because each of these animals have corresponding dielectric constants that are different than the dielectric constant of air, the processor can determine which of the animals is being detected as it enters electrostatic fields 214 and 216 in response to a change in capacitance between the plates. In some embodiments, a memory may be included on the PCB that stores one or more profiles associated with a change in capacitance corresponding to, for example, vehicles of varying size and dimensions that might be driving by or parking next to or near a parked vehicle with one or more capacitive proximity sensor systems. For example, the memory may store a profile associated with an expected change of capacitance corresponding to a bicycle, scooter, motorcycle, sub-compact automobile, compact automobile, midsize automobile, full size automobile, sports utility vehicle (SUV), a lorry (tractor trailer), etc. and the processor may compare the one or more signals that it receives from the capacitive proximity sensor system (e.g., capacitive proximity sensor system 602) to the profiles stored in memory to determine what type of object is within the vicinity of the vehicle, and to determine if an alarm or other action should be taken.

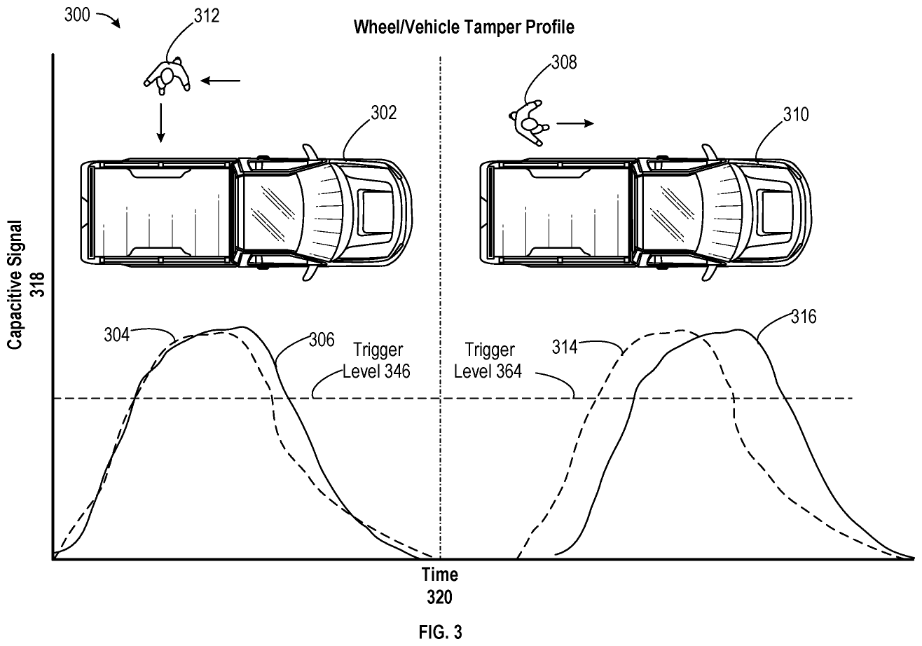

FIG. 3 is a graphical representation of a capacitive proximity sensor system detecting a person within the capacitive proximity sensor system's capacitive sensing field, in accordance with the present disclosure. Graph 300 includes a time axis (Time 320) and capacitive signal axis (Capacitive Signal 318). In this example, as an individual 312 approaches a fender portion of a vehicle 302 the capacitance of the two capacitive sensors in the fender portion will change over time as the change in the dielectric constant of the sensors changes based on the distance the individual is away from the respective sensors. As the individual 312 approaches the vehicle 302, the capacitive signal (change in capacitance) of the two capacitive sensors over time have approximately the same shape. The amplitude of the change in capacitance of a first capacitive sensor, in a capacitive proximity sensor system on vehicle 302, may be capacitive signal 304, and the change in capacitance of a second capacitive sensor, in the capacitive proximity sensor system on vehicle 302, may be capacitive signal 306. The amplitude, time, and shape of capacitive signals 304 and 306 may be similar because individual 312 is approaching the middle of the fender portion housing the capacitive proximity sensor system. That is, the dielectric constant associated with the individual 312 interacts with the electrostatic field of the first capacitive sensor and the electrostatic field of the second capacitive sensor nearly equally over the time that individual 312 interacts with the electrostatic fields of the first capacitive sensor and the second capacitive sensor. The rise in the amplitude of capacitive signal 304 and capacitive signal 306 corresponds to individual 312 approaching the fender portion, and the decline in the amplitude of capacitive signal 304 and capacitive signal 306 corresponds to individual 312 retreating from the fender portion.

Due to the sensitivity of the first capacitive sensor and the second capacitive sensor, the capacitive proximity sensor system can detect when individual 312 is not walking along a straight line perpendicular to the length of the vehicle as they retreat from the fender portion. This is illustrated by the amplitude of capacitive signal 306 declining after the amplitude of capacitive signal 304. In this case, as individual 312 retreats from the fender portion, individual 312 is interacting more with the electrostatic field generated by the second capacitive sensor, which corresponds to capacitive signal 306. Thus, the direction of movement of an individual or vehicle can be determined using two or more capacitive sensors. The capacitive proximity sensor system may determine a time at which capacitive signals 304 and 306 exceed trigger level 346, and determine, based on the time at which capacitive signals 304 and 306 exceed trigger level 346, that an individual is moving in a certain direction. This is illustrated as individual 308 walks along the length of vehicle 310. This holds true for example, when another vehicle is parked next to vehicle 310, because the capacitive proximity sensor system will show a time delay between capacitive signals 314 and 316. The same holds true for other vehicles that are traveling nearby on a road or parking lot.

If the capacitive signals 304 and 306 exceed a threshold, such as Trigger Level 346, for a period of time, then the processor may determine to take certain security actions, such as sending one or more alerts to the user, police, security service, etc., and/or initiate/emit an audible signal or alarm on the vehicle. In some embodiments, the alarm may result in turning on (e.g., activating) exterior image sensors, such as cameras, motion sensors, thermal sensors, infrared sensors, etc., and recording individual 312. In other embodiments, the alert may result in actuation of an audible signal such as a horn or the issuance of a verbal warning from a sound exciter. In some embodiments, the alarm may cause a wireless radio to record wireless signals, such as BLUETOOTH® low energy (BLE) and/or UWB signals, within a distance of the vehicle, such as approximately 10 ft using, using one or more triangulation techniques. The wireless radio may then send BLE messages to wireless radios within the vicinity of the vehicle indicating to individuals nearby that the external image sensors will be activated and will record their movements if they do not move. In another example, the alarm may cause a wireless radio to record Ultra Wide-band (UWB) signals within a distance of the vehicle, such as approximately 10 ft using one or more triangulation techniques. The wireless radio may then send UWB messages to wireless radios within the vicinity of the vehicle indicating to individuals nearby that the external image sensors will be activated and will record their movements if they do not move. The alert may cause the processor to send a message to a mobile device associated with the user of the vehicle using a cellular radio. The message may be sent to an application on the user's mobile device, or to a short message service (SMS) application on the user's mobile device. The message may include audio, video, and/or still photo capture of the area around the vehicle.

As the individual 308 walks along the length of vehicle 310, capacitive signal 314 may rise before capacitive signal 316, and exceed the trigger level 364 prior to the capacitive signal 316. This is due to the fact that the capacitance of a first capacitive sensor, of a capacitive proximity sensor system, generating capacitive signal 314, changes first due to individual 308 interacting with the electrostatic field generated by the first capacitive sensor before interacting with the electrostatic field generated by the second capacitive sensor.

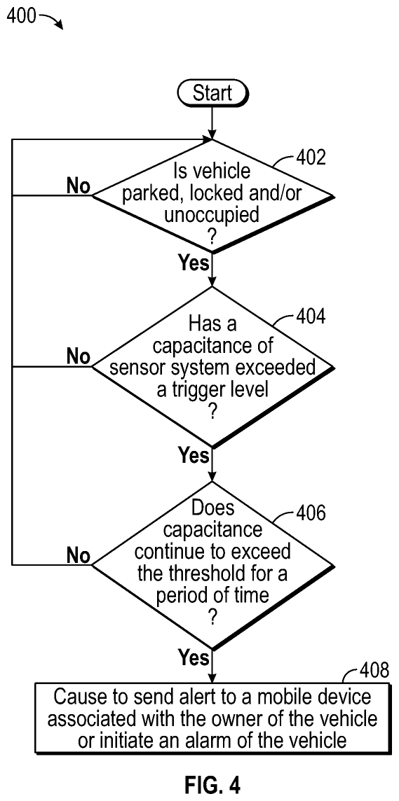

FIG. 4 is a flowchart 400 of an example method of the present disclosure related to detecting an individual or vehicle in a capacitive sensing field of a capacitive proximity sensor system. The method may include a step 402 to determine whether the vehicle is parked, locked, and/or unoccupied. One or more of these or other criteria may be used to determine when to activate or measure the output of the capacitive proximity sensor systems on the vehicle. If the activation criteria are not satisfied, condition (No), then the method may return to step 402. If the method does determine that the activation criteria are satisfied condition (Yes), then the method may proceed to step 404. At step 404, the method may determine whether a capacitance of a capacitive proximity sensor system has exceeded a trigger level. For example, when a capacitive signal such as capacitive signal 304 or capacitive signal 306 exceeds trigger level 346. The capacitive signal corresponds to a change in capacitance.

If the condition is not satisfied the method may return to step 402. The method may determine whether a capacitance associated with a capacitive sensor has exceeded the trigger level as explained above. For example, as shown in FIG. 3, when either capacitive signal 304 or capacitive signal 306 exceed trigger level 346 it may be determined that the capacitance associated with a capacitive sensor has exceeded the trigger level. At step 406, once the trigger level has been exceeded, the method may determine whether the capacitance associated with a capacitive sensor continues to exceed the trigger level for a trigger level period of time, which may be set as a time threshold. If the condition is not satisfied, then the method may return to step 402. If the wheel sensor capacitance does not continue to exceed the trigger level for the trigger level period of time, the capacitance may have exceeded the trigger level for a transient period of time associated with, for example, an individual, animal, or another vehicle passing by the capacitive sensor. It is unlikely that the cause of a short period of the sensor capacitance being above the threshold is an individual attempting to remove the wheel from the vehicle. If the condition in step 406 is satisfied, then the method may proceed to step 408 and may initiate an alert to a mobile device associated with the user of the vehicle or initiate an alarm or alarm mode of the vehicle, which may result in the horn going off, the lights flashing, sending of an SMS message, and/or the capture of video and/or sound.

The processor may determine that an individual is kneeling in front of one, or both, of the two capacitive sensors in the capacitive proximity sensor system for a period of time that exceeds the trigger level period of time required to fill the tire with air and may be attempting to change or remove the tire . The trigger level period of time may be based at least in part on statistical data collected on the time it takes someone to fill a tire versus remove a tire. Further, if the amount of time to fill a tire was exceeded, but valid vehicle key is detected in the cabin or the zone of the tire or vehicle, it may be determined that the owner or another authorized person is attempting to change the tire versus someone attempting to steal the tire.

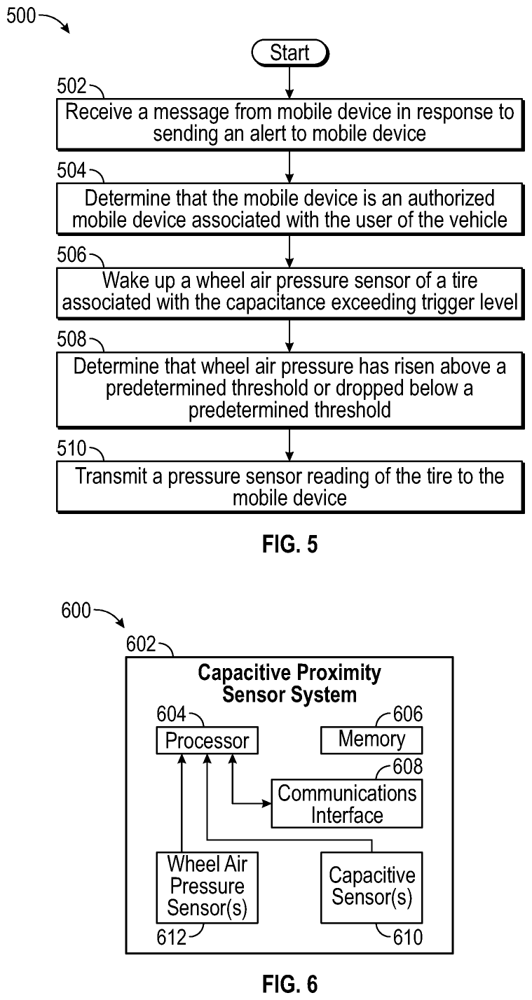

FIG. 5 is a flowchart 500 of an example method of the present disclosure related to detecting a person in a capacitive sensing field of a capacitive proximity sensor system. In some embodiments, the method may receive a message, at block 502, from the mobile device of the user in response to sending the alert to the mobile device of the user in block 408. At block 504, the method may recognize the mobile device as an authorized mobile device that is near the vehicle (using triangulation), and determine that there is movement near the wheel of the vehicle, and may wake up a wheel air pressure sensor associated with wheel (block 506). At block 508, the method may determine whether the pressure in the tire of the wheel has risen above a certain trigger or fallen below a certain trigger. In some embodiments, the method may determine whether the number of pounds per square inch (psi) of pressure added to the tire is above a certain trigger, or the number of PSI of pressure removed from the tire is below a certain trigger. At block 510, the method may transmit a pressure sensor reading to the user's mobile device once per second. If pressure does not change after 3 seconds have elapsed, the method may stop transmitting pressure sensor reading.

Turning now to the drawings, FIG. 6 depicts an illustrative architecture 600 in which techniques and structures of the present disclosure may be implemented. In various embodiments, the vehicles mentioned herein, for example vehicle 222, include a capacitive proximity sensor system such as capacitive proximity sensor system 602, as may be provided for via a PCB, such as PCB 114.

In some embodiments, the capacitive proximity sensor system 602 comprises a processor 604 and memory 606. The memory 606 stores instructions that are executed by the processor 604 to perform aspects of the distracted condition analysis and warning disclosed herein. When referring to operations executed by the capacitive proximity sensor system 602 it will be understood that this includes the execution of instructions by the processor 604.

Capacitive proximity sensor system 602 may be affixed to the inside of a fender portion of a vehicle. Capacitive proximity sensor system 602 may be part of or in communication with one or more other processors of a vehicle, such as the electronic control units (ECU) or body control mechanism (BCM), that control aspects of the operations of the vehicle 222, and the components described herein may be part of capacitive proximity sensor system 602 or other components of the car, such as communications interface 608.

For example, capacitive proximity sensor system 602 may be affixed to the inside of fender 108. Capacitive proximity sensor system 602 may be electrically coupled to the capacitive sensors, such as sensors 104 and 106, and the associated driven ground 102, vis connectors passing through the fender 108, as illustrated in FIG. 1B.

Processor 604 may perform the same functions as those described with general reference to the processor throughout the application. That is the processor may perform the steps in FIGS. 4 and 5. Capacitive sensor(s) 610 may comprise the first capacitive sensor and a second capacitive sensor referenced above. Processor 604 may receive signals from a detector circuit (not shown) that may be included in capacitive proximity sensor system 602 that indicate when the capacitance of one or both of capacitive sensor(s) 610 has changed. Wheel air pressure sensor(s) 612 may measure the pressure in a tire of a wheel as explained above.

Communications interface 608 may be equipped with one or more wireless radios including cellular radios (e.g., GSM-UMTS, CDMA, WCDMA, LTE, 5G, etc.), low power wireless local area network radios (e.g., BLUETOOTH® radios), wireless local area network radios (e.g., Wireless Fidelity (Wi-Fi) radios). Processor 604 may send and receive signals to a processor inside the cab of vehicle 222 via communications interface 608. Processor 604 may also send and receive signals to a processor in a mobile device associated with a user of vehicle 222 via a cellular radio, low power wireless local area network radio, and/or a wireless local area network radio.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

It should also be understood that the word “example” as used herein is intended to be non-exclusionary and non-limiting in nature. More particularly, the word “exemplary” as used herein indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices such as those listed above and stored on a computer-readable medium.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method comprising:
determining that a vehicle is parked;
receiving information indicative of a capacitance at a first sensor positioned proximate a wheel well of the vehicle;
determining, based on the information, that the capacitance exceeds a first threshold for a period of time, and that the period of time exceeds a second threshold; and
causing to send a message to a mobile device.

2. The method of claim 1, further comprising:
causing to activate one or more image sensors associated with the vehicle.

3. The method of claim 1, wherein the first sensor is integrated into a trim piece associated with the wheel well.

4. The method of claim 1, further comprising:
causing the vehicle to emit an audible signal.

5. The method of claim 1, further comprising:
determining that one or more wireless signals have been received by the vehicle, and
causing to send a second message, the second message indicating that the vehicle is being monitored.

6. The method of claim 1, further comprising:
determining that a change in air pressure of a tire on the vehicle exceeds a first rate of change; and
wherein sending the message to the mobile device is based on the change in air pressure exceeding the rate of change.

7. The method of claim 1, further comprising receiving second information indicative of a second capacitance at a second sensor positioned proximate a second wheel well of the vehicle.

8. The method of claim 7, further comprising:
determining a third capacitance by the first sensor at the wheel well of the vehicle at a first time;
determining a fourth capacitance by the second sensor at the second wheel well of the vehicle at a second time, the second time after the first time, wherein a difference between the second time and the first time is below a third threshold; and
determining that an object has passed by the first wheel well and then the second wheel well of the vehicle.

9. A system comprising:
a first sensor; and
at least one processor, wherein the at least one processor executes computer-executable instructions stored in a memory, thereby configuring the at least one processor to:
determine that a vehicle is parked;
receive information indicative of a capacitance at the first sensor positioned proximate a wheel well of the vehicle;
determine based on the information that the capacitance exceeds a first threshold for a period of time, and that the period of time exceeds a second threshold; and
cause to send a message to a mobile device.

10. The system of claim 9, wherein the at least one processor is further configured to: perform at least one of:
activate on one or more image sensors associated with the vehicle, or emit an audible message by the vehicle.

11. The system of claim 9, wherein the at least one processor is further configured to:
determine that one or more wireless signals have been received by the vehicle; and
cause to send a second message, the second message indicating that the vehicle is being monitored.

12. The system of claim 9, wherein the at least one processor is further configured to:
receive second information indicative of a second capacitance at a second sensor positioned proximate a second wheel well of the vehicle; and
determine based on the second information, that the second capacitance exceeds a second threshold for a period of time, and that the period of time exceeds a third threshold.

13. The system of claim 12, wherein the at least one processor is further configured to:
determine a third capacitance by the first sensor at the wheel well of the vehicle at a first time;
determine a fourth capacitance by the second sensor at the second wheel well of the vehicle at a second time, the second time after the first time, wherein a difference between the second time and the first time is below a fourth threshold; and
determine that an object has passed by the first wheel well and then the second wheel well of the vehicle based on the third and fourth capacitances exceeding a fifth threshold.

14. The system of claim 12, wherein the second sensor is integrated into a trim piece associated with the second wheel well.

15. A proximity sensor system for a vehicle, comprising:
a first capacitive sensor associated with a wheel well of the vehicle;
a second capacitive sensor associated with the wheel well of the vehicle;
a air pressure sensor associated with a first wheel at the first wheel well of the vehicle;
a processor in communication with the first capacitive sensor, the second capacitive sensor, and the air pressure sensor, the processor configured to:
determine at least one of a first capacitance detected by the first capacitive sensor or a second capacitance detected by the second capacitive sensor exceeds a first threshold for a period of time, and that the period of time exceeds a second threshold;
determine an air pressure of a tire on the first wheel changes at a rate that exceeds a first value during the period of time; and
cause to send a message to a mobile device.

16. The proximity sensor system of claim 15, wherein the processor is further configured to activate one or more image sensors associated with the vehicle.

17. The proximity sensor system of claim 15, wherein the first capacitive sensor and the second capacitive sensor are integrated into a trim piece associated with the vehicle.

18. The proximity sensor system of claim 15, wherein the processor is further configured to transmit ultra wide band (UWB) signals, wherein the UWB signals include an indication that the vehicle is monitoring activity around the vehicle.

19. The proximity sensor system of claim 15, wherein the processor is further configured to send an air pressure measurement form the air pressure sensor to the mobile device.

20. The proximity sensor system of claim 15, further comprising a ground reference associated with the first capacitive sensor and the second capacitive sensor.
